(19) United States
(12) Patent Application Publication
(10) Pub. No.: US 2015/0060854 A1
(43) Pub. Date: Mar. 5, 2015

(54) SEMICONDUCTOR DEVICE AND METHOD OF MANUFACTURING THE SAME

(71) Applicant: SK hynix Inc., Gyeonggi-do (KR)

(72) Inventors: Sang-Hoon SHIN, Gyeonggi-do (KR); Sang-Jin BYEON, Gyeonggi-do (KR)

(73) Assignee: SK hynix Inc., Gyeonggi-do (KR)

(21) Appl. No.: 14/106,790

(22) Filed: Dec. 15, 2013

(30) Foreign Application Priority Data
Aug. 30, 2013 (KR) 10-2013-0104126

(51) Int. Cl. H01L 21/66; G01R 31/28

(52) U.S. Cl. CPC H01L 22/34; H01L 22/14; G01R 31/2884
USPC 257/48; 438/18

(57) ABSTRACT

A semiconductor device includes a main region suitable for performing a first test operation and a second test operation respectively based on a first test signal and a second test signal in a test mode, a first test region electrically connected to the main region and suitable for generating and transferring the first test signal to the main region in the test mode, and a second test region electrically connected to the main region or the first test region with a scribe lane disposed therebetween and suitable for generating and transferring the second test signal to the main region in the test mode.

### CROSS-REFERENCE TO RELATED APPLICATIONS

The present application claims priority of Korean Patent. Application No. 10-2013-0104126, filed on Aug. 30, 2013, which is incorporated herein by reference in its entirety.

### BACKGROUND

1. Field

Exemplary embodiments of the present invention relate to a semiconductor design technology, and more particularly, to a semiconductor device with an effective structure for a test and method of manufacturing the same,

2. Description of the Related Art

Manufacturing a semiconductor device includes a fabrication process in a wafer level, an electrical test in the wafer level, a packaging process and an electrical test in a packaged level.

As such, many test operations are inevitably performed in the course of manufacture of the semiconductor device. A defective device screened through the test operations is discarded.

FIG. 1 is a block diagram illustrating a conventional semiconductor device.

Referring to FIG. 1, the semiconductor device includes a main region 10 and a test region 20.

The main region 10 includes circuits for performing normal operation to meet the purpose of the semiconductor device. For example, the main region 10 of the semiconductor device used as a storage device includes circuits for storing data and the main region 10 of the semiconductor device used as a high-speed operating device such as a central processing unit (CPU) includes circuits for performing a high-speed operation.

The test region 20 includes test circuits for verifying the normal operation of circuits included in the main region 10. The test circuits verify the normal operation of circuits included in the main region 10 through the exchange of a test signal with the circuits of the main region 10.

A plurality of tests are performed in the course of manufacturing a semiconductor device depending on types of the semiconductor device. The test region 20 may be divided into a main test region TEST1 and an auxiliary test region TEST2. The main test region TEST1 includes test circuits for performing essential test operations and the auxiliary test region TEST2 includes test circuits for performing auxiliary test operations.

For example, the main test region TEST1 includes test circuits for performing test operations that are required commonly in a wafer level and a package level, whereas the auxiliary test region TEST2 includes test circuits for performing test operations that are required only in a wafer level and not required henceforward.

For another example, the main test region TEST1 includes test circuits for performing test operations that are essential in a stage of a semiconductor device R&D and required selectively in a wafer level or a package level whereas the auxiliary test region TEST2 includes test circuits for performing test operations that are essential in a stage of a semiconductor device R&D and not required henceforward.

The test region 20 of conventional semiconductor device includes all of the test circuits without distinction of essentiality or continuous requirement although the test circuits for performing the tests are separated into two test regions TEST1 and TEST2.

Therefore, the conventional semiconductor device manufactured to include a region that is not required after fabrication, which causes waste of chip size and standby current.

### SUMMARY

Various embodiments are directed to a semiconductor device with effective test structure that may prevent unnecessary regions from being included therein, and a method of manufacturing the same.

In an embodiment, a semiconductor device may include a main region suitable for performing a first test operation and a second test operation respectively based on a first test signal and a second test signal in a test mode, a first test region electrically connected to the main region and suitable for generating and transferring the first test signal to the main region in the test mode, and a second test region electrically connected to the main region or the first test region with a scribe lane disposed therebetween and suitable for generating and transferring the second test signal to the main region in the test mode.

In an embodiment, a method of manufacturing a semiconductor device may include preparing a substrate in which a normal region and a test region are electrically connected to each other with a scribe lane disposed therebetween, performing a predetermined test operation on the normal region based on a plurality of test signals that are generated in the test region and transferred to the normal region during a wafer test, and removing the test region along the scribe lane after the wafer level test operation.

In an embodiment, a method of manufacturing a semiconductor device may include preparing a substrate having a main region, a first test region and a second region, wherein a second region is separated from the main region or the first test region by a scribe lane, performing a wafer level test operation on main region by using the first test region, and cutting off the first test region from the substrate before packaged, along the scribe lane.

In accordance with the above embodiments, it may be possible to prevent a semiconductor device of which test regions dedicated to pre-packaged test may be removed in the course of manufacture of the device from including unnecessary regions after manufacturing. Further, standby current of the semiconductor device after manufacturing may be minimized.

### BRIEF DESCRIPTION OF THE DRAWINGS

FIG. 1 is a block diagram illustrating a conventional semiconductor device.

FIG. 2 is a block diagram illustrating a semiconductor device in accordance with an embodiment of the present invention.

FIG. 3 is a diagram illustrating electrical connection of a second region to a main region or a first region in the semiconductor device shown in FIG. 2.

### DETAILED DESCRIPTION

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete and will fully convey the scope of the present invention to those skilled in the art. Throughout the disclosure, reference numerals correspond directly to the like numbered parts in the various figures and embodiments of the present invention. It is also noted that in this specification “connected/coupled” refers to one component not only directly coupling another component but also indirectly coupling another component through an intermediate component. In addition, a singular form may include a plural form as long as it is not specifically mentioned in a sentence.

FIG. 2 is a block diagram illustrating a semiconductor device in accordance with an embodiment of the present invention.

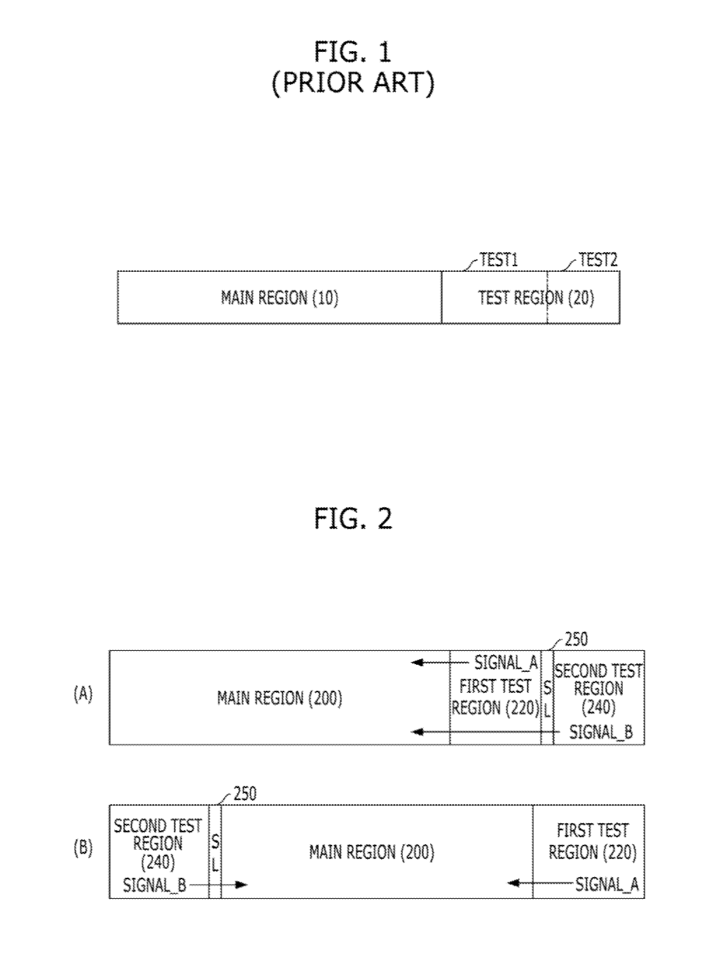

Referring to FIG. 1, the semiconductor device (i.e., a substrate on which predetermined semiconductor fabricating processes have been performed) may include a main region 200, a first test region 220, and a second test region 240.

The main region 200 may include circuits for performing normal operation to meet the purpose of the semiconductor device. For example, the main region 200 of the semiconductor device used as a storage device may include circuits for storing data and the main region 200 of the semiconductor device used as a high-speed processing device such as a central processing unit CPU) may include circuits for performing high-speed operation.

The first test region 220 and the second test region 240 may include test circuits for verifying the normal operation of circuits included in the main region 200. The test circuits may verify the normal operation of circuits included in the main region 200 through communication of test signal with the circuits of the main region 200.

In detail, the first test region 220 may be connected to the main region 200, and may generate and transmit a first test signal SIGNAL_A to the main region 200 during a test mode. The main region 200 in the test mode may receive the first test signal SIGNAL_A and perform a first test operation corresponding to the first test signal SIGNAL_A.

The second test region 240 may be separated from the main region 200 and the first test region 220 by a scribe lane (SL) 250. In case of (B), the second test region 240 is disposed adjacent to the main region 200 while being intermediated by the scribe lane 250. Meanwhile, in case of (A), the second test region 240 is disposed adjacent to the first test region 220 while being intermediated by the scribe lane 250. The second test region 240 may generate and transmit a second test signal SIGNAL_B to the main region 200 during the test mode. The main region 200 in the test mode may receive the second test signal SIGNAL_B and perform a second test operation corresponding to the second test signal SIGNAL_B.

The scribe lane 250, generally, may divide a plurality of semiconductor devices (i.e., substrates or dies) formed on a wafer. The scribe lane 250 may be formed between the semiconductor devices in the wafer level. In the package level, each of the semiconductor devices may be separated from the wafer through cutting off (or sawing) the wafer along the scribe lane 250.

The second test operation for the main region 200 in the wafer level may be performed through the second test region 240. The second test region 240 may be removed (or cut off) after the wafer level test due to the structure of the semiconductor device in which the second test region 240 is separated from the main region 200 and the first test region 220 by the scribe lane 250, while being electrically connected to the main region 200 or the first test region 220. Such structure of the semiconductor device may prevent the semiconductor device from including unnecessary regions after manufacturing.

The second test region 240 divided from the main region 200 and the first test region 220 by the scribe lane 250, may be electrically connected to the main region 200 or the first test region 220. Further, the second test signal SIGNAL_B may be transmitted from the second test region 240 to the main region 200 when the second test region 240 is electrically connected to the first test region 220.

In other words, the second test region 240 may be disposed adjacent to the main region 200 with division by the scribe lane 250. Alternatively, the second test region 240 may be disposed adjacent to the first test region 220 with division by the scribe lane 250. It is meant that the embodiment of the present invention may cover any structure with the scribe lane 250 to be cut off after the wafer level test the second test region 240 from the main region 200 and the first test region 220.

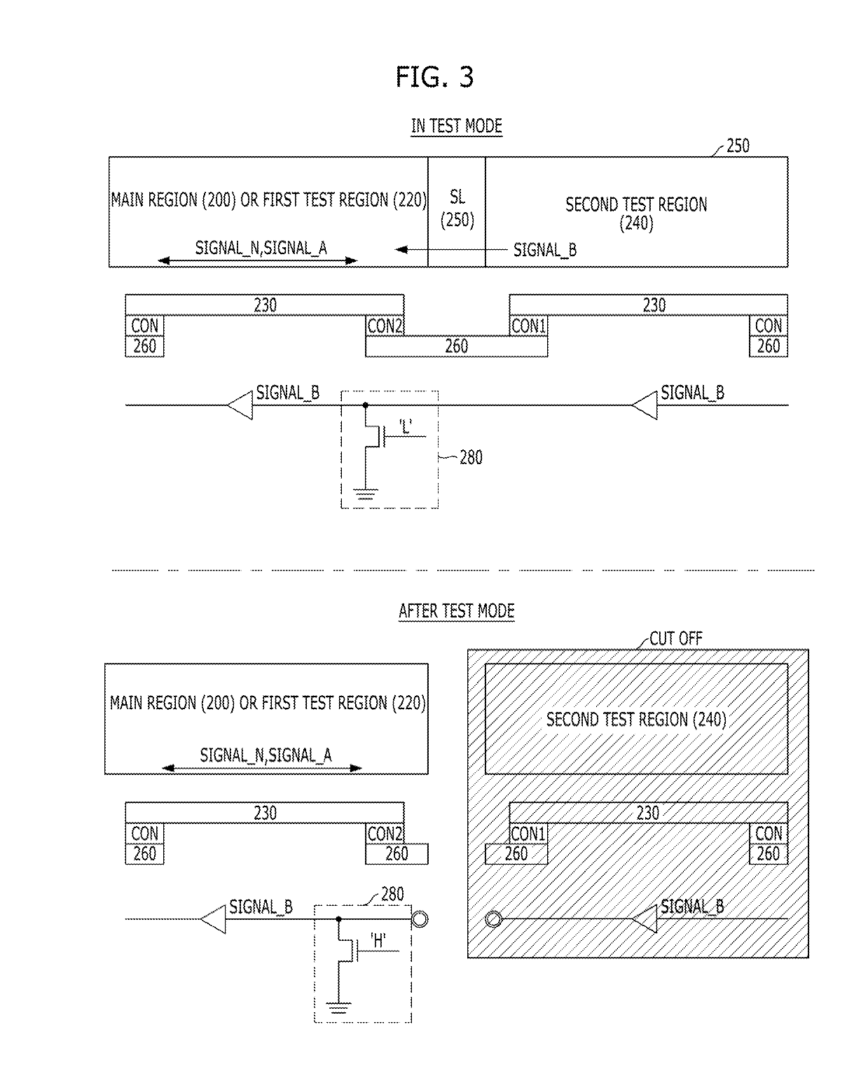

FIG. 3 is a diagram illustrating electrical connection of the second region 240 to the main region 200 or the first region 220 in the semiconductor device shown in FIG. 2.

Referring to FIG. 3, a poly-gate line 260 instead of a metal line 230 may be used as an interconnection for electrical connection of the second test region 240 to the main region 200 or the first test region 220.

In detail, the main region 200, the first test region 220 and the second test region 240 may communicate internal signals N_SIGNAL, A_SIGNAL and B_SIGNAL with one another through the metal line 230 formed therein.

Also, the main region 200 and the first test region 220 may communicate the internal signals N_SIGNAL and A_SIGNAL with each other through the metal line 230 successively formed between the main region 200 and the first test region 220.

However the main region 200 or the first test region 220 and the second test region 240 may communicate the internal signals N_SIGNAL, A_SIGNAL and B_SIGNAL with each other through the poly-gate line 260 independently formed between the main region 200 or the first test region 220 and the second test region 240.

The second test signal SIGNAL_B may be transferred from the second test region 240 to the main region 200 through the poly-gate line 260 and the metal line 230 of the main region 200 when the main region 200 and the second test region 240 are electrically connected by the poly-gate line 260.

The normal signal N_SIGNAL may be transferred from the main region 200 to the second test region 240 through the poly-gate line 260 and the metal line 230 of the second test region 240 when the main region 200 and the second test region 240 are electrically connected by the poly-gate line 260.

The second test signal SIGNAL_B may be transferred from the second test region 240 to the first test region 220 through the poly-gate line 260 and the metal line 230 of the first test region 220 and then transferred together with the first test signal SIGNAL_A from the first test region 220 to the main region 200 through the metal line 230 formed between the main region 200 and the first test region 220 when the first test region 220 and the second test region 240 are electrically connected by the poly-gate line 260.

The normal signal N_SIGNAL may be transferred from the main region 200 to the first test region 220 through the metal line 230 of the first test region 220 and then transferred from the first test region 220 to the second test region 240 through the poly-gate line 260 and the metal line 230 of the second test region 240 when the first test region 220 and the second test region 240 are electrically connected by the poly-gate line 260.

The poly-gate line 260 is formed with such way as a gate electrode of an active device such as a metal oxide semiconductor (MOS) transistor is formed with a conductive material like polysilicon when the active device is formed on a substrate and is used as an interconnection to transfer a signal. The poly-gate line 260 may be formed with ease and without any further process during a fabrication process where the MOS transistor is fabricated on the substrate.

The poly-gate line 260 may be in contact with the metal line 230 of the second test region 240 through a first contact CON1 and with the metal line 230 of the main region 200 or the first test region 220 through a second contact CON2.

The poly-gate line 260 may be formed in a direction substantially perpendicular to the scribe lane 250. The scribe lane 250 may be formed between the second test region 240 and the main region 200 or the first test region 220, and thus the poly-gate line 260 may be formed in a direction substantially perpendicular to the scribe lane 250 for transfer of the signals N_SIGNAL, A_SIGNAL and B_SIGNAL between the second test region 240 and the main region 200 or the first test region 220.

Benefit of the poly-gate line 260 for transfer of the signals N_SIGNAL, A_SIGNAL and B_SIGNAL between the second test region 240 and the main region 200 or the first test region 220 is that the metal line 230 may still hide in the semiconductor device even after the second test region 240 is removed through cut-off of the wafer along the scribe lane 250.

Exposure of the metal line 230 to external may cause corrosion of the device or flowing foreign substance into the device, and thus the benefit of the poly-gate line 260 to allow the metal line 230 to hide in the device advantages the subsequent package level of the semiconductor device.

The main region 200 or the first test region 220, to which the second test region 240 may be connected with the scribe lane 250 disposed therebetween, may include a transmission blocking unit 280 for forcibly disabling transmission of signal on the poly-gate line 260 to the metal line 230 in the main region 200 or the first test region 220 in a mode other than the test mode.

During the test mode where the signals N_SIGNAL, A_SIGNAL and B_SIGNAL are transferred to and from the second test region 240, the signals N_SIGNAL, A_SIGNAL and B_SIGNAL on the poly-gate line 260 may be transferred to the metal line 230 of the main region 200 or the first test region 220. However during the mode other than the test mode after removal of the second test region 240, the signals, which may include unknown signal arbitrarily generated such as a noise, on the poly-gate line 260 should not be transferred to the metal line 230 in the main region 200 or the first test region 220 through forcible disablement of the signals.

The transmission blocking unit 280 may keep a predetermined voltage level, which may be a ground level VSS, of the metal line 230 in the main region 200 or the first test region 220 that may be connected to the poly-gate line 260 during the mode other than the test mode after removal of the second test region 240. The transmission blocking unit 280 may include an NMS transistor directly connected to the metal line 230 in the main region 200 or the first test region 220, which is connected to the poly-gate line 260.

The above described embodiment of the present invention may include the main region 200, the first test region 220 and the second test region 240 under the assumption that there may be constant need for the first test region 220 for essential test because a lot of test may be classified into essential ones and optional ones depending on various levels including the wafer level and the package level.

However, depending on types of a semiconductor device, there may be a case where test operations are simplified or no test circuit is required during test operations after initial tests (e.g., the wafer level test).

Therefore, the semiconductor device in accordance with an embodiment of the present invention may include a normal region including the main region 200 and the first test region 220 and a second test region 240 that may include test circuits for performing test operations that are required only in initial level or the wafer level and not required henceforward. The normal region of the semiconductor device may include circuits required commonly for both of the normal operation and the essential test operation. The second test region 240 may be removed in the course of manufacture of the device after use of the second test region 240 in the initial test.

In accordance with the above-described embodiment of the present invention, the second test region 240 is removed in the wafer level. That is, the second test region 240 is removed in the course of manufacture of the device after use of the second test region 240 in the wafer level.

However, the second test region 240 also may be removed in the course of manufacture of the device after use of the second test region 240 in R&D phase of a semiconductor device. For example, a semiconductor device in the R&D phase may require much more test operations than a semiconductor device in a manufacture phase and most of the test operations in the R&D phase may not be required any more in the manufacture phase.

Unconditionally enlarging auxiliary test region in the semiconductor device of the R&D phase for auxiliary test operations wastes region ineffectively. It is preferable to remove the auxiliary test region such as the second test region 240 of the embodiment of the present invention from the semiconductor device of the R&D phase after use of the auxiliary test region.

According to the embodiment of the present invention, it may be possible to prevent a semiconductor device, of which test regions dedicated to pre-packaged test may be removed in the course of manufacture of the device, from including unnecessary regions after manufacturing. Further, standby current of the semiconductor device after manufacturing may be minimized.

Although various embodiments have been described for illustrative purposes, it will be apparent to those skilled in the art that various changes and modifications may be made without departing from the spirit and scope of the invention as defined in the following claims.

What is claimed is:

1. A semiconductor device comprising:
a main region suitable for performing a first test operation and a second test operation respectively based on a first test signal and a second test signal in a test mode;
a first test region electrically connected to the main region and suitable for generating and transferring the first test signal to the main region in the test mode; and
a second test region electrically connected to the main region or the first test region with a scribe lane disposed therebetween and suitable for generating and transferring the second test signal to the main region in the test mode.

2. The semiconductor device of claim 1, wherein the main region, the first test region and the second test region communicate a signal internally used with each other through a metal line disposed therein,
wherein the first test region transfers the first test signal to the main region through a metal line formed between the main region and the first test region, and
wherein the second test region transfers the second test signal to the main region through a poly-gate line formed between the second test region and the main region or the first test region.

3. The semiconductor device of claim 2, wherein the poly-gate line is formed in a direction perpendicular to the scribe lane.

4. The semiconductor device of claim 2, wherein the poly gate line is in contact with the metal line in the second test region through a first contact and in contact with the metal line in the main region or the first test region through a second contact.

5. The semiconductor device of claim 2, wherein the second test signal is transferred from the second test region to the first test region through the poly-gate line and then transferred from the first test region to the main region through the metal line when the first test region and the second test region are electrically connected by the poly-gate line.

6. The semiconductor device of claim 5, further comprising a transmission blocking unit suitable for forcibly disabling transmission of a signal on the poly-gate line to the metal line in the main region or the first test region in a mode other than the test mode.

7. A method of manufacturing a semiconductor device, the method comprising:
preparing a substrate in which a normal region and a test region are electrically connected to each other with a scribe lane disposed therebetween;
performing a predetermined test operation on the normal region based on a plurality of test signals that are generated in the test region and transferred to the normal region during a wafer test operation; and
removing the test region along the scribe lane after the wafer level test operation.

8. The method of claim 7, wherein the normal region includes a main region and an essential test region, and wherein during the wafer level test operation and a package level test operation, a predetermined essential test operation is performed based on a plurality of essential test signals that are generated in the essential test region and transferred to the main region.

9. The method of claim 7, the test signals that are generated in the test region in the wafer level test operation are transferred to the main region and used for the predetermined test operation.

10. The method of claim 7, wherein the normal region and the test region communicate signals internally used with each other through metal lines disposed therein, and
wherein the test region transfers the test signals to the normal region through respective poly-gate lines formed between the normal region and the test region.

11. The method of claim 10, wherein the poly-gate lines are formed in a direction perpendicular to the scribe lane.

12. The method of claim 10, wherein each of the poly-gate lines is in contact with a corresponding metal line in the test region through a first contact and in contact with the corresponding metal line in the normal region through a second contact.

13. The method of claim 12, wherein the performing of the predetermined test operation, during the wafer level test operation, allows electrical signals on the poly-gate lines to be transferred to the corresponding metal line in the normal region, and
wherein after the wafer level test operation, forcibly disables transmission of the electrical signals on the poly-gate lines to the corresponding metal line in the normal region.

14. A method of manufacturing a semiconductor device, the method comprising:
preparing a substrate having a main region, a first test region and a second region, wherein a second region is separated from the main region or the first test region by a scribe lane;
performing a wafer level test operation on main region by using the first test region; and
cutting off the first test region from the substrate before packaged, along the scribe lane.

15. The method of claim 14, wherein the substrate includes an interconnection for transmitting a test signal between the regions in the wafer level test operation.

16. The method of claim 15 wherein the substrate includes a transmission blocking unit for forcibly disabling transmission of the test signal through the interconnection in a mode other than the wafer level test operation.
